(19) United States
(12) Patent Application Publication
(10) Pub. No.: US 2006/0125547 A1
(43) Pub. Date: Jun. 15, 2006

(54) Adjustable and programmable temperature coefficient-proportional to absolute temperature (APTC-PTAT) circuit

(76) Inventors: Mohammad Maymandi-Nejad, Waterloo (CA); Manoj Sachdev, Waterloo (CA)

Correspondence Address: Charles N.J. Ruggiero, Esq.;Ohlandt, Greeley, Ruggiero & Perle, L.L.P., 10th Floor, One Landmark Square, Stamford, CT, 06901-2682, US

(21) Appl. No.: 11/190,441

(22) Filed: Jul. 27, 2005

Related U.S. Application Data
(60) Provisional application No. 60/591,144, filed on Jul. 27, 2004.

(51) Int. Cl. H01L 35/00

(52) U.S. Cl. 327/512

(57) ABSTRACT

An adjustable PTAT provides a load current comprising at least a first and second current. The load current has a desired temperature coefficient and the PTAT comprises at least two transistor groups. The first transistor group provides the first current having a negative temperature coefficient. Modification to the first transistor group results in a change in the temperature coefficient without affecting the value of the first current. The second transistor group provides the second current having a positive temperature coefficient, wherein modification to the second transistor group results in a change in the temperature coefficient without affecting the value of the second current. The temperature coefficient of the load current is determined by adjusting the temperature coefficient of one or both of the first and second transistor groups.

The present invention relates generally to proportional to absolute temperature (PTAT) circuits and specifically to PTAT circuits having an adjustable and programmable temperature coefficient. This application claims priority from U.S. Provisional Application No. 60/591,144 filed 27 Jul. 2004.

### BACKGROUND OF THE INVENTION

Biasing circuits are an important part of analog very large-scale integration (VLSI) design. Specifically, the stability of these circuits with respect to temperature, supply voltage and other environmental variations is extremely important. This is due to the effect the biasing current and/or voltage has on the behaviour of other analog blocks in an integrated circuit (IC).

Further, besides biasing networks for pure analog circuits, there are other applications in which a stable voltage or current is needed as a reference. Examples of circuits requiring such a reference include memory sense amplifiers and high precision instrumentation circuits.

However, transistor characteristics are temperature dependent and, as a consequence, the overall electronic circuit performance changes with temperature. In several applications especially instrumentation, bio-medical applications, and the like, the circuit must be made insensitive to temperature variations.

Accordingly, in order to achieve a stable bias circuit with a stable bias voltage or current, several techniques have been proposed. A popular one of these techniques is referred to as the band gap reference voltage and is well known in the art. A majority of these circuits include a proportional to absolute temperature (PTAT) circuit as a major component. PTAT circuits generate a voltage or current proportional to the absolute temperature, which can be used to provide a stable, temperature independent voltage or current reference source.

However, the design of PTAT circuits is not a trivial task, especially for low voltage circuits. Referring to FIG. 1(a) a basic PTAT based reference voltage generator is illustrated generally by numeral 100. The reference voltage generator 100 includes a PTAT circuit 102, a gain stage 104, and a transistor 106 connected in a diode configuration. The temperature coefficient (TC) of a voltage or current in a circuit depends on the elements used in that circuit and the circuit architecture. The output voltage of the PTAT circuit 102 has a positive temperature coefficient (TC) while the voltage across the diode connected transistor 106 has a negative TC. Summing the PTAT circuit 102 and the transistor 106 with proper weights, one can realize a stable reference voltage with a small TC.

Referring to FIG. 1(b) a typical PTAT circuit implemented using meta-oxide semiconductor field effect transistors (MOSFETs) is illustrated generally by numeral 150. The operation of this circuit is described in greater detail in K. Kimura's “Low Voltage Techniques for Bias Circuits,” IEEE Trans. on Circuits and Systems I: Fundamental Theory and Applications, Vol. 44, May 1997. Current I_{B} is almost independent of power supply voltage (VDD) and has a fixed TC. Further, Giustolisi et. al. “A Low-Voltage Low-Power Voltage Reference Based on Subthreshold MOSFETs,” IEEE Journal of solid state circuits, Vol. 38, No. 1, January 2003, describe a circuit for providing a reference voltage with a TC of 36 ppm/°K.

In a PTAT the TC should be within a pre-defined range. For example, in the voltage reference circuit illustrated in FIG. 1(a), the TC of the PTAT 102 compensates the TC of the transistor 106 within in given temperature range.

However, designing a PTAT circuit with a pre-defined TC is a nontrivial task. The problem of having a specified TC becomes even more difficult in low voltage circuits. Designing PTATs with a specific TC, even though difficult, is possible. In order to achieve this result, several circuit parameters must be manipulated in order to achieve the desired TC of the PTAT. This parametric manipulation is a difficult task since several of these parameters influence each other.

Accordingly, PTAT circuits often have a fixed TC that cannot be modified easily. Thus it can be seen that there is a need for a PTAT whose temperature coefficient can be adjusted and programmed with relative ease.

### SUMMARY OF THE INVENTION

In accordance with an aspect of the invention there is provided an adjustable PTAT for providing a load current comprising a first and second current, the load current having a desired temperature coefficient and the PTAT comprising: a first transistor group for providing the first current having a negative temperature coefficient, wherein modification to the first transistor group results in a change in the temperature coefficient without affecting the value of the first current; and a second transistor group for providing the second current having a positive temperature coefficient, wherein modification to the second transistor group results in a change in the temperature coefficient without affecting the value of the second current; wherein the temperature coefficient of the load current is determined by adjusting the temperature coefficient of one or both of the negative and positive temperature coefficients.

### BRIEF DESCRIPTION OF THE DRAWINGS

An embodiment of the present invention will now be described by way of example only with reference to the following drawings in which:

FIG. 1a is a circuit diagram for generating a reference voltage using a PTAT (prior art);

FIG. 1b is a circuit diagram of the PTAT circuit illustrated in FIG. 1a (prior art);

FIG. 2 is a graph illustrating the TC₁ versus the V_{GS} of a MOSFET in the saturation region;

FIG. 3a is a graph illustrating the TC₁ versus the V_{GS} of a MOSFET in the linear region;

FIG. 3b is a graph illustrating the TC₁ versus the V_{DS} in the linear region for different values of V_{GS};

FIG. 4 is a circuit diagram of a PTAT in accordance with an embodiment of the present invention;

FIG. 5 is a model diagram of the PTAT illustrated in FIG. 4;

FIG. 6 is an alternate model diagram of the PTAT illustrated in FIG. 4 showing how a load current can comprise a number of current sources in series or in parallel to the load;

FIG. 7 is a circuit diagram of a PTAT and a voltage regulator;

FIG. 8 is a circuit diagram of a programmable PTAT; and

FIG. 9 is a graph illustrating the measured temperature behaviour of the circuit illustrated in FIG. 8 implemented in 0.18 μm CMOS technology.

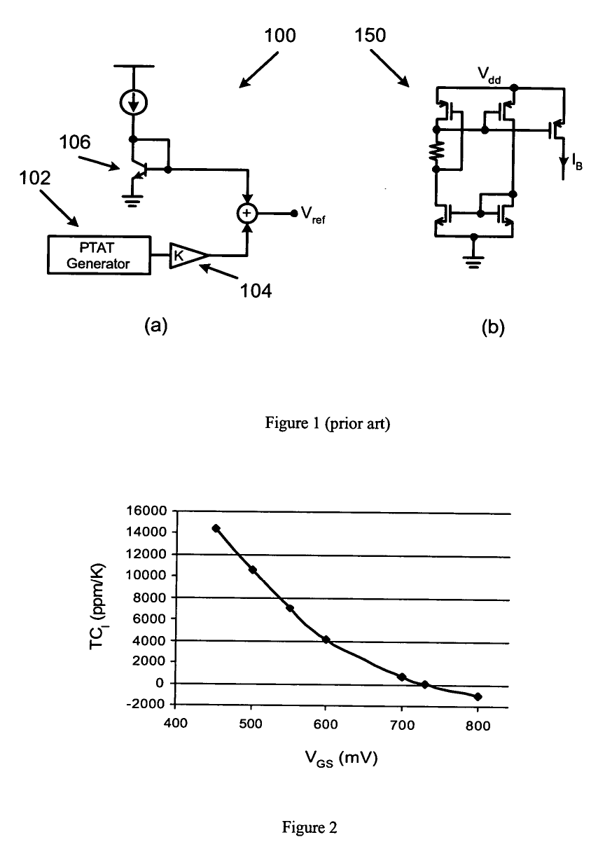

### DETAILED DESCRIPTION OF THE PREFERRED EMBODIMENT

For convenience, like numerals in the description refer to like structures in the drawings. The temperature behaviour of a MOSFET transistor is different in saturation and linear regions. In the saturation region the drain current is represented by the following equation:

$${I}_{D} = \frac{{C}_{ox} W}{2 l} μ {( T ) [ {V}_{GS} - {V}_{Th} ( T ) ]}^{2} \qquad ( 1 )$$

In Equation 1, both μ and V_{Th} are functions of the temperature, as per I. M. Filanovsky, A. Allam, “Mutual compensation of Mobility and Threshold Voltage Temperature Effects with Applications in CMOS Circuits,” IEEE Trans. On Circuits and Systems I: Fundamental Theory and Applications, Vol. 48, July 2001, and can be expressed as:

$$\begin{matrix}μ ( T ) = μ {( \frac{T}{{T}_{o}} )}^{- {k}_{μ}} {k}_{μ} = 1.2 - 2 & ( 2 ) \\ {V}_{Th} ( T ) = {V}_{T 0} - {k}_{v} ( T - {T}_{0} ) {k}_{v} = 0.5 - 3 mV / {}^{o} K & ( 3 )\end{matrix}$$

From Equations 1 and 3, the temperature dependence of V_{Th} causes the drain current I_{D} to increase as T increases. From Equations 1 and 2, the opposite is true for the temperature dependence of μ, and the drain current I_{D} decreases as μ increases. As a result of this dual dependency, there is a V_{GS} in the saturation region, where the temperature coefficient of I_{D} (TC₁) becomes negligibly small. In the case of analyzed 0.18 μm complementary metal-oxide semiconductor (CMOS) technology, this V_{GS} is approximately 730 mV. Simulation results of a single negative-channel metal-oxide semiconductor (NMOS) in 0.18 μm CMOS technology confirm this observation. Table 1 below provides the simulation results for the TC₁ of an NMOS in the range of 27° C. to 37° C.

TABLE 1

| | | | | | | | | |
|---|---|---|---|---|---|---|---|---|
| V_{DS}(mV) | 900 | 900 | 900 | 900 | 900 | 900 | 900 | 1200 |
| V_{GS}(mV) | 450 | 500 | 550 | 600 | 700 | 800 | 730 | 730 |
| TC_{I}(ppm/° K) | 14404 | 10617 | 7015 | 4137 | 644 | −1055 | 8.8 | 12.6 |

Referring to FIG. 2, a graph illustrating TC₁ as a function of V_{GS} is shown. It has been shown that the width-to-length ratio and V_{DS} of the NMOS transistor does not affect the TC₁ noticeably. Moreover, the relationship is also largely independent of the absolute level of the drain current.

However, the temperature behaviour of a MOSFET transistor is different in the linear region. In the linear region the drain current is obtained from the following equation:

$${I}_{D} = \frac{{C}_{0 x} W}{L} μ ( T ) [ \text{(} {V}_{GS} - {V}_{Th} ( T ) {V}_{DS} - \frac{{V}_{DS}^{2}}{2} ] \qquad ( 4 )$$

Substituting Equations 2 and 3 into Equation 4 and taking the derivative ID in Equation 4 with respect to temperature T, we get the following equation:

$$\frac{\partial {I}_{D}}{\partial T} = \frac{{C}_{ox} W}{L} {μ}_{0} \{ [ \frac{- {k}_{μ}}{{T}_{0}} {( \frac{T}{{T}_{0}} )}^{- {k}_{μ} - 1} ] [ {V}_{GS} - {V}_{Th} ( T ) {V}_{DS} - \frac{{V}_{DS}^{2}}{2} ] + {( \frac{T}{{T}_{0}} )}^{- {k}_{μ}} {k}_{v} {V}_{DS} \} \qquad ( 5 )$$

As can be seen the TC₁ in the linear region depends on both V_{GS} and V_{DS}. Further, it can also be shown that TCI is a monotonically increasing function of V_{DS}:

$$\frac{\partial {I}_{D}}{\partial T} = 0 ⇒ {V}_{DS , 0} = 2 ( {V}_{GS} - {V}_{Th} ( T ) ) + \frac{2 {Tk}_{v}}{{k}_{μ}} \qquad ( 6 )$$

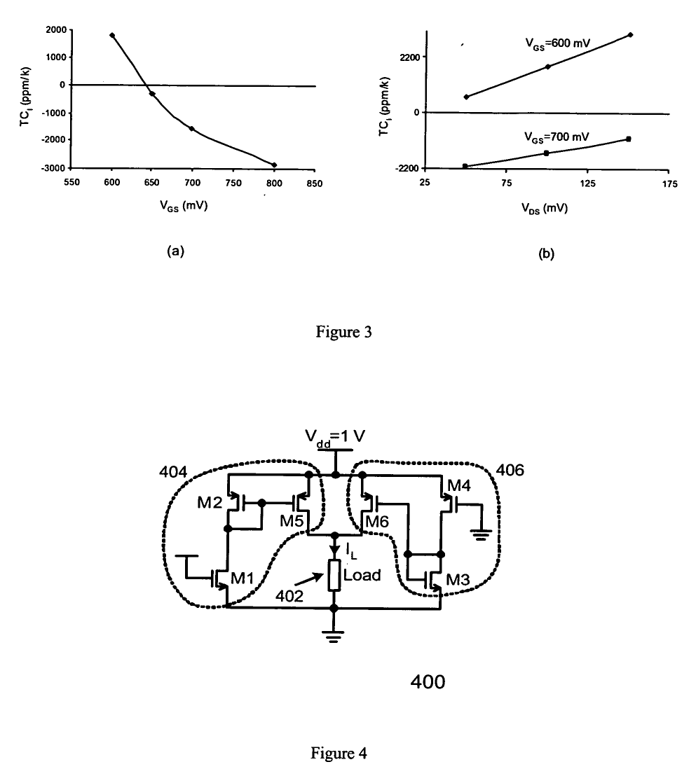

In Equation 6, V_{DS,0} is the value of V_{DS} at which ∂I_{D}/∂T=0. For V_{DS}<V_{DS,0}, TC₁ increases as V_{DS} increases and vice versa. However, in the linear region the inequality V_{DS}<(V_{GS}−V_{Th}) is true. Therefore, in the linear region V_{DS} is always less than V_{DS,0} and hence TC₁ monotonically increases as V_{DS} rises. However, TC₁ can be either positive or negative depending the value of V_{GS}. For large values of V_{GS}, TC₁ is negative. Tables 2 and 3 show the simulation results of an NMOS transistor in the linear region in 0.18 μm CMOS technology in the range of 27° C. to 37° C. Table 2 illustrates how TC₁ changes with respect to V_{GS} while holding V_{DS} constant. Table 3 illustrates how TC₁ changes with respect to V_{DS} for different values of V_{GS}. The results of these tables are illustrated in FIGS. 3a and b.

TABLE 2

| | | | | |
|---|---|---|---|---|
| V_{DS}(mV) | 100 | 100 | 100 | 100 |
| V_{GS}(mV) | 600 | 650 | 700 | 800 |
| TC_{I}(ppm/° K) | 1827 | −281 | −1585 | −2862 |

TABLE 3

| | | | | | | |
|---|---|---|---|---|---|---|
| V_{DS}(mV) | 50 | 100 | 150 | 50 | 100 | 150 |
| V_{GS}(mV) | 600 | 600 | 600 | 700 | 700 | 700 |
| TC_{I}(ppm/° K) | 626 | 1827 | 3100 | −2077 | −1585 | −992 |

Based on the discussion and results above, it seems that biasing a MOSFET in the linear region provides more flexibility for adjusting the temperature coefficient of the drain current. This feature will be useful in making a PTAT circuit with adjustable TC₁. It should be noted that a MOSFET has a temperature independent biasing point. However, this normally happens at V_{GS} voltages that are quite high and may not be applicable in a low voltage circuit.

The following describes a proposed circuit for implementing an adjustable and programmable-temperature coefficient PTAT (APTC-PTAT) circuit. A feature of the proposed circuit is the ability of the PTAT circuit to have an adjustable TC with few independent parameters, while limiting the effect on other specifications. Further, the proposed circuit may be programmed in the field to have a specific TC.

Referring to FIG. 4, an adjustable PTAT circuit is illustrated generally by numeral 400. The circuit comprises six MOSFET transistors M1, M2, M3, M4, M5 and M6, a voltage supply V_{dd} and a load 402. In the present embodiment, transistors M2, M5, M6 and M4 are p-channel transistors and transistors M1 and M3 are n-channel transistors. Transistors M1, M2 and M5 form a first transistor group 404 and transistors M3, M4 and M6 form a second transistor group 406. Further, the transistors M1 to M6 have been fabricated using 0.18 μm CMOS technology.

Transistors M2 and M5 are coupled gate-to-gate and both have their source coupled to the voltage supply V_{dd}. The gate of transistor M2 is further coupled to its drain and the drain of transistor M1. Transistor M1 is gated by the voltage supply V_{dd} and is coupled to ground at its source.

Transistors M4 and M6 are coupled at the source to the voltage supply V_{dd}. Further, the drain of transistor M4 is coupled to the gate of transistor M6 and both the gate and drain of transistor M3. Transistor M4 is gated by ground. Transistor M3 is coupled at the source to ground.

The drain of transistors M5 and M6 are coupled together via the load 402 to ground. A load current I_{L} running through the load 402 is a combination of currents I₁ and I₂ running though transistors M5 and M6 respectively.

In this circuit, the temperature behavior of the transistors M1 and M4 in the linear region are manipulated advantageously. That is, the overall TC of the load current I_{L} can be adjusted since the TC of the load current I_{L} depends on the TC of the drain current I₁ and I₂ of transistors M5 and M6.

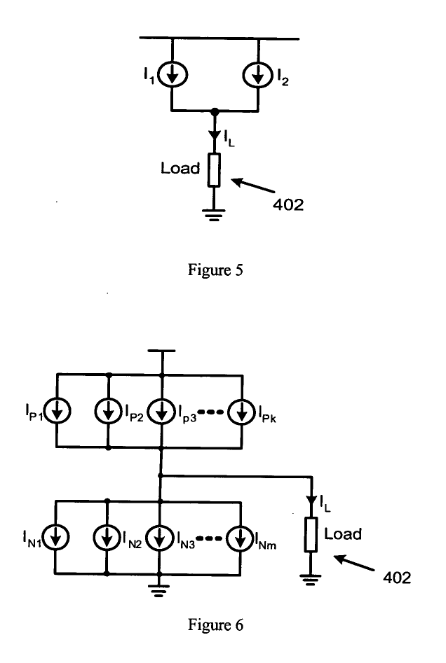

Referring to FIG. 5, a model of the circuit illustrated in FIG. 4 is shown generally by numeral 500. The model is used to verify the assumption made above. The model comprises two current sources 502 and 504 and the load 402. The first current source 502 generates a first current I₁ and the second current source generates a second current I₂. Therefore, it can be seen that I_{L}=I₁+I₂. Further, this equation can be manipulated as follows:

$$\frac{\partial {I}_{L}}{\partial T} = \frac{\partial {I}_{1}}{\partial T} + \frac{\partial {I}_{2}}{\partial T} \\ \frac{1}{{I}_{L}} \frac{\partial {I}_{L}}{\partial T} = \frac{{I}_{1}}{{I}_{L}} \frac{\partial {I}_{1}}{{I}_{1} \partial T} + \frac{{I}_{2}}{{I}_{L}} \frac{\partial {I}_{2}}{{I}_{2} \partial T} \\ {TCI}_{L} = \frac{{I}_{1}}{{I}_{L}} {TCI}_{1} + \frac{{I}_{2}}{{I}_{L}} {TCI}_{2} \qquad ( 7 )$$

From Equation 7, it is clear that the TC of the load current I_{L} can be modified by adjusting the TCs of its current components I₁ and I₂.

The idea of composing the load current from two individual currents with separate TCs can be extended to any number of currents in series or in parallel to the load as shown in FIG. 6. In the circuit of FIG. 6 the TC of the load current can be obtained as the following:

$${I}_{L} = ( {I}_{P 1} + {I}_{P 2} + … {I}_{Pk} ) - ( {I}_{N 1} + {I}_{N 2} + … {I}_{Nm} ) \\ \frac{\partial {I}_{L}}{\partial T} = \frac{\partial {I}_{P 1}}{\partial T} + \frac{\partial {I}_{P 2}}{\partial T} + … + \frac{\partial {I}_{Pk}}{\partial T} - \frac{\partial {I}_{N 1}}{\partial T} - \frac{\partial {I}_{N 2}}{\partial T} - … - \frac{\partial {I}_{Nm}}{\partial T} \\ {TCI}_{L} = \frac{1}{{I}_{L}} ( {\sum }_{i = 1}^{k} {I}_{Pi} {TCI}_{Pi} - {\sum }_{i = 1}^{m} {I}_{Ni} {TCI}_{Ni} ) \qquad ( 8 )$$

Referring once again to FIG. 4, the first transistor group 404 (transistors M1, M2, and M5) provides one of the current sources shown in FIG. 3 and is designed to have a negative TC. Similarly, the second transistor group 406 (transistors M3, M4, and M6) provides the other current source shown in FIG. 5 and is designed to have a positive TC.

In the first transistor group 404, transistor M2 is operating in the saturation region. This can be seen from the equation V_{DS}≦V_{GS}−V_{T}, which defines the condition for saturation region operation in a p-channel MOSFET. In the present embodiment, V_{DS}=V_{GS}, since the drain is coupled to the gate. Thus, the equation becomes V_{T}≦0. For 0.18 μm CMOS the threshold voltage VT of a p-channel MOSFET is around −0.4V and the condition is always met. Accordingly, the transistor M2 operates in the saturation region.

The equation V_{DS}≦V_{GS}−V_{T} defines the condition for linear region operation in an n-channel MOSFET. Since V_{GS}=1V for transistor M1 and assuming V_{T}=0.4 V, as long as V_{DS}≦0.6V the transistor M1 will operate in the linear region, as desired. In the present embodiment V_{DS} is less than 0.5V, which can be achieved by proper sizing of M1 and M2.

Further, it can be seen that the transistors M2 and M5 are configured as a current mirror.

Transistor M2 is used primarily to mirror the current of transistor M1 into transistor M5.

As discussed with reference to Tables 2 and 3, for large values of V_{GS}, the TC is negative. Accordingly, the TC for transistor M1, TC₁, is negative. Further, since transistor M2 is only used to mirror the current of transistor M1 into transistor M5 the TC of M5, TCI₁, relies primarily on TC₁. Accordingly, TCI₁ depends on the V_{DS} of transistor M1, which can be adjusted by changing the size of transistor M2. However, changing the size of transistor M2 causes a change in I₁. In order to keep the I₁ constant the size of transistor M5 is also changed accordingly to keep the current of transistor M5 (I₁) constant. This feature provides flexibility to adjust TCI₁ of the transistor M5 without changing the value of its current I₁.

Referring to the second group of transistors 406, transistor M4 is also biased in the linear region. This can be seen from a brief review of the circuit. Transistor M3 is an n-channel transistor. Accordingly, operation in the saturation region for an n-channel transistor is governed by the equation V_{DS}≦V_{GS}−V_{T}. Since V_{DS}=V_{GS} and V_{T}≈0.4 V, the condition is always true and the transistor M3 is biased in the saturation region. Further, in order to turn on transistor M3, V_{DS}=V_{GS}>V_{T}. Thus, for transistor M4, V_{DS}>−0.6V. Since M4 is a p-channel transistor, operation in the linear region is governed by the equation V_{DS}≧V_{GS}−V_{T}. Since V_{GS}=−1 V, this condition is always true and the transistor M4 is biased in the linear region.

As discussed with reference to Tables 2 and 3, for large absolute values of V_{GS}, the TC is negative. However, unlike the first group of transistors 404, the second group of transistors 406 does not include a current mirror. Rather, the current I₂ passing through transistor M6 largely depends on the voltage at its gate, which is determined by the equation V_{GS6}=V_{GS3}−V_{dd}. The value of the temperature coefficient of I₂ (TCI₂) can be adjusted by the size of M3 which in turn changes |V_{DS}| for transistor M4. This causes M4 to have an adjustable negative TC. The gate-source voltage of M6 is equal to V_{GS3}−V_{dd}. Therefore, the TC of M6 depends on the TC of M4 as well as the TC of M3 (V_{GS3}).

From equations 1-3, it is clear that V_{GS3} has a negative temperature coefficient. Since the current going into M3 has also a negative TC, V_{GS3} has a larger negative adjustable TC compared to a transistor driven by a constant current with zero TC. Since V_{GS3} has a negative adjustable TC, its value decreases as temperature increases. Therefore, since V_{GS6}=V_{GS3}−V_{dd}, |V_{GS6}| increases as temperature increases. This causes M6 to have a positive adjustable TC and the adjustment of the TC can be achieved by selectively sizing M3.

From the above discussion, it is clear that the load illustrated in FIG. 4 is driven by two current sources, a first current source I₂ with a positive, adjustable TC and a second current source I₁ with a negative, adjustable TC. Note that TCs of the two current sources driving the load can be adjusted independently of the load current and of each other. Therefore, the temperature coefficient of the load current I_{L} can be adjusted to either a positive or negative value or even set to zero depending on the requirements of the load circuit. For example, if it is known that the load circuit 402 is designed using components that are insensitive to temperature change, it may be desirable to provide a load current I_{L} with small or zero TC. If, however, it is determined that the load circuit 402 is sensitive to temperature change, the load current I_{L} can be designed to compensate and minimize the effect of the change.

An assumption in the present embodiment is that the supply voltage V_{dd} is constant. However, often the supply voltage V_{dd} changes with temperature and other environmental effects. In applications where a battery provides supply voltage V_{dd}, the aging of the battery may cause the supply voltage V_{dd} to change over time. Therefore, in some cases it may be useful to accompany the PTAT with a voltage regulator.

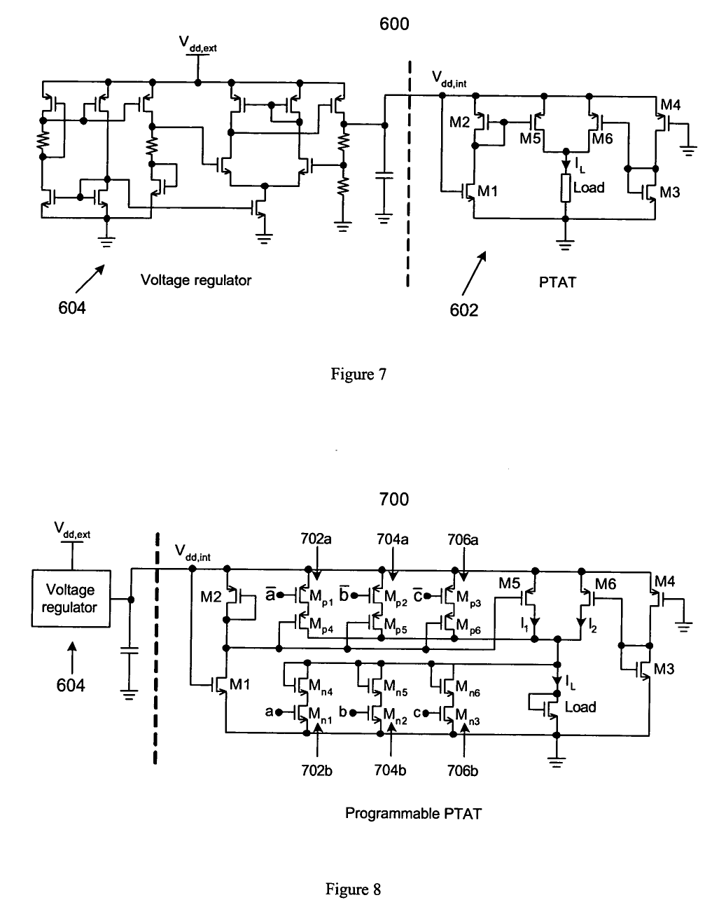

Referring to FIG. 7, a PTAT circuit is illustrated generally by numeral 600. The circuit comprises a PTAT portion 602 and a voltage regulator 604. The voltage regulator 604 is known in the art and need not be described in detail. Further, a person of ordinary skill in the art will appreciate that other voltage regulator implementation may be used.

However, it should be noted that even though the voltage regulator 604 reduces V_{dd} variations, the output of the voltage regulator 604 may still have a non-zero TC. Fortunately, the TC of the voltage regulator 604 can also be compensated by the PTAT circuit. Therefore, in order to efficiently design the entire circuit 600, the voltage regulator 604 should be designed to minimize the voltage variations of the external voltage supply V_{dd}. Then the TC of the output voltage of the regulator should be estimated and considered when determining the size of the transistors in the PTAT circuit 602.

Referring once again to Equation 7, it is clear that the TC of the load current I_{L} can be adjusted by changing either the value of TCI₁ and/or TCI₂ or changing the ratio of I₁ and I₂ to the overall load current I_{L}. In the description above, the first approach was described. Here, the second approach is used to add programmability to the PTAT circuit.

Referring to FIG. 8, a PTAT circuit in accordance with an alternate embodiment of the present invention is illustrated generally by numeral 700. The circuit 700 is similar to the circuit 400 illustrated in FIG. 4, except for a plurality of switch circuits 702a, 704a, and 706a parallel to transistor M5, and a plurality of switch circuit 702b, 704b, and 706b parallel to the load 402. Each of the switch circuits 702a, 704a, and 706a includes a switch transistor M_{P1}, M_{P2}, and M_{P3}, respectively, and a sizing transistor M_{P4}, M_{P5}, and M_{P6}, respectively. Each sizing transistors has its gate coupled with the gate of transistor M5, its drain coupled with the drain of transistor M5, and its source coupled, via a corresponding switch transistor to the voltage supply V_{dd}. Each of the switch transistors M_{P1}, M_{P2}, and M_{P3} are sized much larger than the sizing transistors so that they operate as a switch. Further, they are controlled by a signal complementary to the digital input vector (a, b, c).

Similarly, each of the switch circuits 702b, 704b, and 706b includes a switch transistor M_{P1}, M_{P2}, and M_{P3}, respectively, and a sizing transistor M_{N4}, M_{N5}, and M_{N6}, respectively. Each sizing transistors has its gate coupled with its drain to the drain of transistor M5, and its source coupled, via a corresponding switch transistor to ground. Each of the switch transistors M_{N1}, M_{N2}, and M_{N3} are sized much larger than the sizing transistors so that they operate as a switch. Further, they are controlled by the digital input vector (a, b, c).

In the present embodiment, transistors M_{P4} to M_{P6} are added to change the ratio of I₁ and I₂ in Equation 7 by changing the value of I₁. This is achieved by the current mirror configuration of transistors M5 and M2. As the ratio between transistors M5 and M2 changes, so does the size of the current I₂ in transistor M5.

However, this causes the load current I_{L} to change. Therefore, in order to keep I_{L} constant, transistors M_{N3} to M_{N6} are used to remove the additional current from I_{L}. Transistors M_{P4} to M_{P6} and M_{N4} to M_{N6} are sized in a binary fashion. In this way, eight different TCs can be programmed by changing the value of the digital input vector. A person skilled in the art will appreciate that the number of switch circuits may be modified to accommodate a differently sized digital input vector.

Although the load current illustrated in FIG. 8 comprises two current sources, as described with reference to FIG. 6, it is possible to design a circuit with more than two current sources. In this case the adjustment/programmability mechanism illustrated in FIG. 8 for adjusting the TC of the load current can be applied to more than one current source.

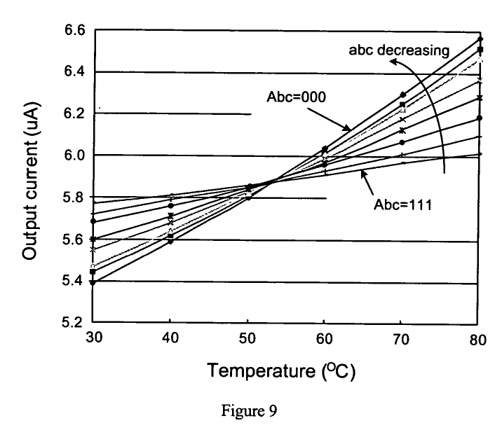

Referring to FIG. 9, a graph illustrating the temperature behavior of the circuit 700, implemented in 0.18 μm CMOS technology, is shown. The graph illustrates the output current of the circuit 700 with respect to temperature. The digital input (a,b,c) changes the TC of the current without affecting the output current itself, which is constant. This fact is illustrated by the single point of intersection at approximately 53° C. for each curve representing a different TC. The current variation versus temperature can be considered linear within a limited temperature range, for example 32° C. to 42° C., which is the case for biomedical applications.

Although preferred embodiments of the invention have been described herein, it will be understood by those skilled in the art that variations may be made thereto without departing from the spirit of the invention or the scope of the appended claims.

What is claimed is:

1) An adjustable temperature coefficient proportion to absolute temperature (PTAT) circuit for providing a load current comprising a first and second current, the load current having a desired temperature coefficient, the PTAT comprising:
a) a first transistor group for providing the first current having a negative temperature coefficient, wherein modification to the first transistor group results in a change in the temperature coefficient without affecting the value of the first current; and
b) a second transistor group for providing the second current having a positive temperature coefficient, wherein modification to the second transistor group results in a change in the temperature coefficient without affecting the value of the second current;
wherein the temperature coefficient of the load current is determined by adjusting the temperature coefficient of one or both of the first and second transistor groups.

2) The PTAT of claim 1, wherein the first and second transistor group comprise MOSFET transistors which are manipulated in one of the linear or saturated regions for providing current sources with specific temperature coefficients.

3) The PTAT of claim 2, wherein adjustability of the temperature coefficient for each of the first and second transistor groups is facilitated by modifying a transistor drain-source voltage in the linear region for at least one of the transistors.

4) The PTAT of claim 1 further comprising one or more switch stages coupled in parallel with one of the transistor groups, each switch stage comprising a serially coupled switch and transistor.

5) The PTAT of claim 4, wherein the temperature coefficient is dynamically programmable via a digital input vector as a control signal to the switches.

6) The PTAT of claim 5, wherein the digital input vector enables one or more of the switches, thereby modifying an effective size of at least one of the transistors for varying the temperature coefficient.

7) The PTAT of claim 1, wherein the load current comprises a plurality of current sources in series with or parallel to the load current.
